(19) United States
(12) Patent Application Publication
(10) Pub. No.: US 2011/0139219 A1
(43) Pub. Date: Jun. 16, 2011

(54) SUPPORTING AND COOLING STRUCTURE OF PHOTOVOLTAIC MODULE

(75) Inventors: Hsieh-Hsin Yeh, Sanchong City (TW); Chi-Lai Lee, Pingzhen City (TW)

(73) Assignee: Du Pont Apollo Limited, Pak Shek Kok (HK)

(21) Appl. No.: 12/956,884

(22) Filed: Nov. 30, 2010

Related U.S. Application Data
(60) Provisional application No. 61/286,357, filed on Dec. 14, 2009.

(51) Int. Cl. H01L 31/052

(52) U.S. Cl. 136/246

(57) ABSTRACT

A supporting and cooling structure and a photovoltaic module with the same are described. The supporting and cooling structure includes a supporting frame to fix a photovoltaic panel of the photovoltaic module, and a supporting and cooling member fixed on the supporting frame. The supporting and cooling member touches the photovoltaic panel to further support the photovoltaic panel and to transmit a heat on the photovoltaic panel to the supporting frame therethrough.

### RELATED APPLICATIONS

This application claims priority to U.S. Provisional Application Ser. No. 61/286,357, filed Dec. 14, 2009, which is herein incorporated by reference.

### FIELD OF THE INVENTION

The present invention generally relates to a photovoltaic module. More particularly, this invention relates to a supporting and cooling structure of a photovoltaic module.

### BACKGROUND OF THE INVENTION

The increasing scarcity and the realization of the ecological and safety problems associated with non-renewable energy resources such as coal, petroleum and uranium, have made it essential that increased use be made of alternate non-depletable energy resources such as solar energy. Solar energy use has been limited in the past to special applications due in part to the high cost of manufacturing devices capable of producing significant amounts of photovoltaic energy. The improvement in manufacturing technology for fabricating the solar panel in mass production has greatly promoted the use of solar energy.

Significant environmental benefits are also realized from solar energy production, for example, reduction in air pollution from burning fossil fuels, reduction in water and land use from power generation plants, and reduction in the storage of waste byproducts. Solar energy produces no noise, and has few moving components. Because of their reliability, solar panels also reduce the cost of residential and commercial power to consumers.

There is a need to continuously improve the efficiency of the photovoltaic module. An effective way of improving efficiency of the photovoltaic module is by reducing the operating temperature of the photovoltaic module. Therefore, some of the conventional photovoltaic modules can achieve this target by cooling the photovoltaic module with a water cooling system or an external cooling module. However, the water cooling system or the external cooling module can make the photovoltaic module more complicated and the manufacturing cost thereof higher.

### SUMMARY OF THE INVENTION

One objective of the present invention is to provide a supporting structure which is able to reduce the operating temperature of the photovoltaic module.

To achieve these and other advantages and in accordance with the objective of the present invention, as the embodiment broadly describes herein, the present invention provides a supporting and cooling structure for a photovoltaic module. The supporting and cooling structure includes a supporting frame for fixing a photovoltaic panel and a supporting and cooling member fixed on the supporting frame. The supporting and cooling member touches the photovoltaic panel to further support the photovoltaic panel and to transmit the heat from the photovoltaic panel to the supporting frame through the supporting and cooling member.

In one embodiment, the supporting frame is made of aluminum and the supporting and cooling member is integrated with the supporting frame.

In another embodiment, the supporting and cooling member is made of sheet metal.

In addition, the supporting and cooling member can touch the front glass substrate of the photovoltaic panel or touch the back sheet of the photovoltaic panel.

In another aspect of the present invention, the present invention provides a photovoltaic module. The photovoltaic module includes a supporting frame, a photovoltaic panel fixed on the supporting frame, and a supporting and cooling member fixed on the supporting frame. The supporting and cooling member touches the photovoltaic panel to further support the photovoltaic panel and to transmit a heat on the photovoltaic panel to the supporting frame through the supporting and cooling member.

In one embodiment, the supporting frame is made of aluminum and the supporting and cooling member is integrated with the supporting frame.

In another embodiment, the supporting and cooling member is made of sheet metal.

The photovoltaic panel includes a front substrate and a back sheet, and the supporting and cooling member can be in contact with the front substrate, e.g. a glass substrate, of the photovoltaic panel, or the back sheet of the photovoltaic panel.

The photovoltaic module can further include a cushion member disposed between the photovoltaic panel and the supporting frame to prevent the supporting frame from damaging the photovoltaic panel. The cushion member can be made of rubber or a polymer material. The heat conducting property of the supporting and cooling member is better than the heat conducting property of the cushion member.

Accordingly, the supporting and cooling structure according to the present invention can effectively reduce the operating temperature of the photovoltaic panel and improve the efficiency of the photovoltaic module. In addition, the supporting and cooling structure according to the present invention can not only effectively support the photovoltaic panel but also effectively dissipate the heat on the photovoltaic panel.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a photovoltaic module with a supporting and cooling structure according to the present invention;

FIG. 2 illustrates a partially enlarged view of an embodiment of a photovoltaic module with a supporting and cooling structure according to the present invention;

FIG. 3 illustrates a partially enlarged view of another embodiment of a photovoltaic module with a supporting and cooling structure according to the present invention; and

FIG. 4 illustrates a rear view of a photovoltaic module with a supporting and cooling structure according to the present invention.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

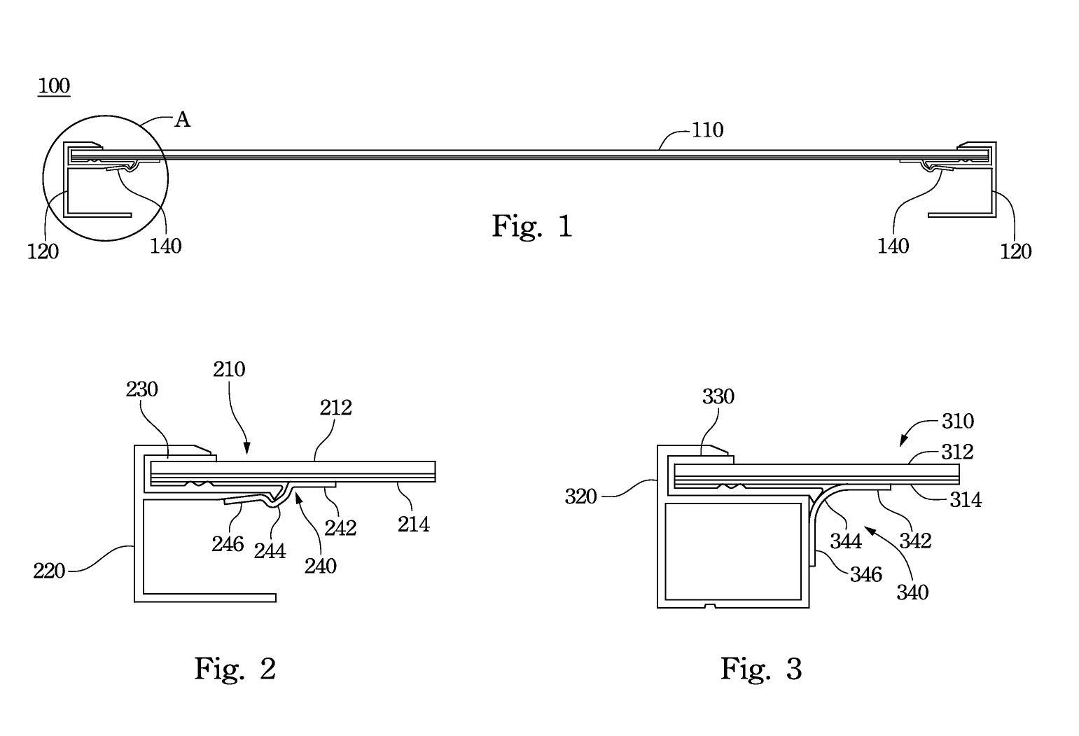

Refer to FIG. 1. FIG. 1 illustrates a photovoltaic module with a supporting and cooling structure according to the present invention. The photovoltaic module 100 includes a photovoltaic panel 110 fixed in a supporting and cooling structure. In addition, the supporting and cooling structure further includes a supporting frame 120 and a supporting and cooling member 140. The supporting and cooling member 140 directly contacts the supporting frame 120 and the photovoltaic panel 110 to further support the photovoltaic panel 110 and to transmit the heat generated from the photovoltaic panel 110 to the supporting frame 120.

Further refer to FIG. 2. FIG. 2 illustrates a partially enlarged view of an embodiment of a photovoltaic module with a supporting and cooling structure according to the present invention. The photovoltaic panel 210 is fixed in a supporting frame 220 with a cushion member 230 and the cushion member 230 is made of an elastic material, e.g. a rubber material or a polymer material, which can prevent the photovoltaic panel 210 from damage by directly contacting the supporting frame 220 made of metal material, for example, aluminum. However, the cushion member 230 is a poor heat conducting material. A supporting and cooling member 240 is further fixed on the supporting frame 220. In one embodiment, the supporting and cooling member 240 includes a supporting arm 242, a connecting portion 244 and a fixing arm 246. Alternatively, the supporting and cooling member 240 and the supporting frame 220 can be separately formed, and then the supporting and cooling member 240 is fixed on the supporting frame 220 without departing from the spirit and scope of the present invention. Still furthermore, in one embodiment, the supporting and cooling member 240 and the supporting frame 220 can be, but not used to limit the scope of the present invention, a monolithic structure according to the demands. This means that the supporting and cooling member 240 is integrated with the supporting frame 220, which can be manufacturing by extrusion.

The supporting and cooling member 240 can be made of a metal material, e.g. aluminum or a sheet metal, with a good heat conducting property better than that of the cushion member 230. The supporting and cooling member 240 is preferably a flexible member to contact with the back sheet 214 of the photovoltaic panel 110 and prevent from damage to the photovoltaic panel 110. The back sheet 214 can be a Tedlar® PVF film manufactured by Dupont, or a laminated film composite, TPT™, manufactured by Dupont.

Refer to FIG. 3. FIG. 3 illustrates a partially enlarged view of another embodiment of a photovoltaic module with a supporting and cooling structure according to the present invention. The photovoltaic panel 310 is also fixed in a supporting frame 320 with a cushion member 330 and the cushion member 330 is made of an elastic material, e.g. a rubber material or a polymer material, which can prevent the photovoltaic panel 310 from damage by directly contacting the supporting frame 320 made of metal material, for example, aluminum. However, the cushion member 330 is a poor heat conducting material. A supporting and cooling member 340 is further fixed on the supporting frame 320. The supporting and cooling member 340 includes a supporting arm 342, a connecting portion 344 and a fixing arm 346. In an embodiment, the supporting and cooling member 340 can be integrated with the supporting frame 320 according to the demands. In another embodiment, the supporting and cooling member 340 and the supporting frame 320 can be separately formed, and then the supporting and cooling member 340 is fixed on the supporting frame 320 without departing from the spirit and scope of the present invention.

The supporting and cooling member 340 can be made of a metal material, e.g. aluminum or a sheet metal, with a good heat conducting property better than the cushion member 330. In addition, the connecting portion 344 is an arc, and the supporting arm 342 and the fixing arm 346 are respectively extended from the two ends of the connecting portion. Furthermore, the supporting and cooling member 340 is preferably a flexible member to contact with the back sheet 314 of the photovoltaic panel 110 and prevent from damage to the photovoltaic panel 110.

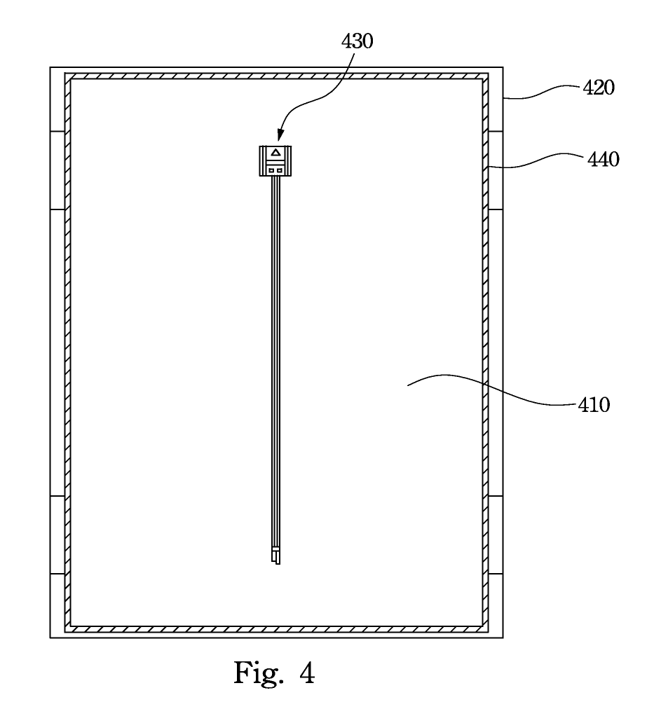

Refer to FIG. 4. FIG. 4 illustrates a rear view of a photovoltaic module with a supporting and cooling structure according to the present invention. The photovoltaic module includes a photovoltaic panel 410, a supporting frame 420, a junction box 430, and a supporting and cooling member 440. The supporting frame 420 is to fix the photovoltaic panel 410. The supporting and cooling member 440 is fixed on the supporting frame 420 to further support the photovoltaic panel 410. The junction box 430 is fixed onto the back sheet of the photovoltaic panel 410 to accommodate output terminals and output cables therein, such that the electricity generated from the photovoltaic module can be output. In one embodiment, the supporting and cooling member 440 is a rectangular member extending from or fixing on the supporting frame 420. The supporting frame 420 is larger than the supporting and cooling member 440, and the heat of the photovoltaic panel 410 can be transmitted to the supporting frame 420 through the supporting and cooling member 440. The supporting and cooling member 440 can be configured on the rear side of the photovoltaic panel 410. Alternatively, the supporting and cooling member 440 can be configured on the front substrate, e.g. the glass substrate 212 of FIG. 2 or the glass substrate 312 of FIG. 3, of the photovoltaic panel without departing from the spirit and scope of the present invention. In another embodiment, the supporting and cooling member 440 can be a detachable rectangular member. Alternatively, the supporting and cooling member 440 can also be an elongated shape disposed on at least one side of the supporting frame 420 according to the demands.

Accordingly, the supporting and cooling structure according to the present invention can effectively reduce the operating temperature of the photovoltaic panel so as to improve the efficiency of the photovoltaic module. In one experiment, the operating temperature of the photovoltaic panel having the supporting and cooling structure according to the present invention can be reduced about 8 degrees centigrade so that the efficiency and the lifespan of the photovoltaic module are effectively improved.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A photovoltaic module, comprising:
a supporting frame;
a photovoltaic panel fixed on the supporting frame; and
a supporting and cooling member fixed on the supporting frame, and the supporting and cooling member in contact with the photovoltaic panel to further support the photovoltaic panel and transmit a heat on the photovoltaic panel to the supporting frame through the supporting and cooling member.

2. The photovoltaic module of claim 1, wherein the supporting frame is made of aluminum.

3. The photovoltaic module of claim 1, wherein the supporting and cooling member is integrated with the supporting frame.

4. The photovoltaic module of claim 1, wherein the supporting and cooling member is made of aluminum.

5. The photovoltaic module of claim 1, wherein the supporting and cooling member is made of sheet metal.

6. The photovoltaic module of claim 1, wherein the photovoltaic panel comprises a front substrate and a back sheet.

7. The photovoltaic module of claim 6, wherein the supporting and cooling member touches the front substrate of the photovoltaic panel.

8. The photovoltaic module of claim 7, wherein the front substrate is a glass substrate.

9. The photovoltaic module of claim 6, wherein the supporting and cooling member touches the back sheet of the photovoltaic panel.

10. The photovoltaic module of claim 1, further comprising a cushion member disposed between the photovoltaic panel and the supporting frame.

11. The photovoltaic module of claim 10, wherein the cushion member is made of rubber.

12. The photovoltaic module of claim 10, wherein the cushion member is made of polymer material.

13. The photovoltaic module of claim 10, wherein a heat conducting property of the supporting and cooling member is better than a heat conducting property of the cushion member.

14. A supporting and cooling structure for a photovoltaic module, comprising:
a supporting frame for fixing a photovoltaic panel; and
a supporting and cooling member fixed on the supporting frame, and the supporting and cooling member in contact with the photovoltaic panel to further support the photovoltaic panel and transmit a heat on the photovoltaic panel to the supporting frame through the supporting and cooling member.

15. The supporting and cooling structure for a photovoltaic module of claim 14, wherein the supporting frame is made of aluminum.

16. The supporting and cooling structure for a photovoltaic module of claim 14, wherein the supporting and cooling member is integrated with the supporting frame.

17. The supporting and cooling structure for a photovoltaic module of claim 14, wherein the supporting and cooling member is made of aluminum.

18. The supporting and cooling structure for a photovoltaic module of claim 14, wherein the supporting and cooling member is made of sheet metal.

19. The supporting and cooling structure for a photovoltaic module of claim 14, wherein the supporting and cooling member touches the front glass substrate of the photovoltaic panel.

20. The supporting and cooling structure for a photovoltaic module of claim 14, wherein the supporting and cooling member touches the back sheet of the photovoltaic panel.
